(19) United States
(12) Patent Application Publication
(10) Pub. No.: US 2010/0315087 A1
(43) Pub. Date: Dec. 16, 2010

(54) APPARATUS AND METHOD OF MAGNETIC RESONANCE IMAGING

(75) Inventors: Keith R. Thulborn, Bannockburn, IL (US); Theodore C. Claiborne, Lake Zurich, IL (US); Ian Atkinson, Oak Park, IL (US); Aiming Lu, Chicago, IL (US)

Correspondence Address: UIC Docket, 304 Indian Trace Rd, #750, Weston, FL, 33326, US

(73) Assignee: THE BOARD OF TRUSTEES OF UNIVERSITY OF ILLINOIS, Urbana, IL (US)

(21) Appl. No.: 12/866,805

(22) PCT Filed: Feb. 12, 2009
(86) PCT No.: PCT/US2009/033960

§ 371 Date: Aug. 9, 2010

Related U.S. Application Data
(60) Provisional application No. 61/028,003, filed on Feb. 12, 2008.

(51) Int. Cl. G01R 33/44

(52) U.S. Cl. 324/318

(57) ABSTRACT

A system that incorporates teachings of the present disclosure may include, for example, a Magnetic Resonance Imaging system comprising a Magnetic Resonance (MR) scanner to selectively couple to one among a plurality of antennas without compromising spatial alignment with an anatomical sample during signal acquisition by the MR scanner. According to one embodiment, the invention teaches to replace a single-tuned antenna tuned to a first resonance frequency by another single-tuned antenna tuned to a different resonance frequency in the course of an MRI experiment (e.g. metabolic quantification).

### PRIOR APPLICATION

The present application claims the priority of U.S. provisional patent application No. 61/028,003 filed Feb. 12, 2008, entitled Magnetic Resonance Imaging, Attorney Docket no. 7940-21 (DA081). All sections of the aforementioned application are incorporated herein by reference.

### FIELD OF THE DISCLOSURE

The present disclosure relates generally to magnetic resonance imaging, and more specifically to an apparatus and method of magnetic resonance imaging.

### BACKGROUND

Clinical magnetic resonance imaging (MRI) is based on the MR signal that arises from the hydrogen nucleus, where the hydrogen is chemically bonded to oxygen in water or carbon in fat. Metabolic MRI uses signals that come from the nuclei of protons and other low atomic weight elements (e.g. sodium, phosphorus, oxygen, carbon, nitrogen, etc.) to generate images. Because these non-proton signals are much weaker, the resolution of these metabolic images is reduced for a given acquisition time. Signals from different nuclei are detected at different frequencies. The hardware for performing MR imaging requires an antenna, in which the sample is placed, that is tuned to resonate at the frequency of the MR signal to be detected.

### BRIEF DESCRIPTION OF THE DRAWINGS

FIG. 1 depicts an illustrative embodiment of an apparatus for performing magnetic resonance imaging (MRI) measurements on a sample;

FIG. 2 depicts an illustrative embodiment of side view of the apparatus of FIG. 1;

FIGS. 3-4 depict illustrative embodiments of first and second antennas for engaging with the apparatus of FIG. 1;

FIGS. 5-7 depict illustrative embodiments of the composition of the antennas and connectors for engagement therewith;

FIG. 8 depicts an illustrative embodiment for engaging either of the first and second antennas of FIGS. 3-4 with the apparatus of FIG. 1;

FIG. 9 depicts an illustrative embodiment of either of the first and second antennas of FIGS. 3-4 engaged with the apparatus of FIG. 1;

FIG. 10 depicts an illustrative embodiment of a perspective view of FIG. 9;

FIG. 11 depicts an illustrative embodiment of FIG. 9 with a patient engaged in the apparatus with one of the antennas of FIGS. 3-4 overlaying a portion of the patient;

FIG. 12 depicts an illustrative embodiment for interconnecting the antennas of FIGS. 3-4 to an MRI system;

FIG. 13 depicts an illustrative embodiment of FIG. 11 with a patient engaged in the apparatus with one of the antennas of FIGS. 3-4 overlaying a portion of the patient and a normalization phantom positioned above the patient's head;

FIG. 14 depicts an illustrative embodiment of a spherical phantom for calibration purposes;

FIG. 15 depicts an illustrative embodiment of FIG. 11 with the spherical phantom of FIG. 14 engaged in the apparatus with one of the antennas of FIGS. 3-4 overlaying a portion of the spherical phantom and the normalization phantom;

FIG. 16 depicts an illustrative embodiment of cylindrical phantoms for calibration purposes;

FIG. 17 depicts an illustrative embodiment of two cylindrical phantoms coupled to one of the antennas of FIGS. 3-4;

FIG. 18 depicts an illustrative embodiment of FIG. 11 with a patient engaged in the apparatus with one of the antennas of FIGS. 3-4 overlaying a portion of the patient and the pair of cylindrical phantoms coupled to an inner surface of the antenna; and

FIG. 19 depicts an exemplary diagrammatic representation of a machine in the form of a computer system within which a set of instructions, when executed, may cause the machine to perform any one or more of the methodologies disclosed herein.

### DETAILED DESCRIPTION

One embodiment of the present disclosure entails a device having a plurality of antennas to couple to a Magnetic Resonance Imaging (MRI) system, wherein the MRI system measures a first set of signals from a first one of the antennas while the first antenna is positioned over an anatomical sample and engaged with the MRI system, and wherein the MRI system measures a second set of signals from a second one of the antennas engaged with the MRI system after the second antenna replaces the first antenna while maintaining image alignment with the anatomical sample.

Another embodiment of the present disclosure entails an MRI system comprising a Magnetic Resonance (MR) scanner to selectively couple to one among a plurality of antennas without compromising spatial alignment with an anatomical sample during signal acquisition by the MR scanner.

Yet another embodiment of the present disclosure entails a computer-readable storage medium having computer instructions for processing signals received from at least two among a plurality of antennas that selectively couple to an MR scanner without compromising spatial alignment with an anatomical sample during signal acquisition by the MR scanner.

Another embodiment of the present disclosure entails a method for selectively coupling one among a plurality of antennas to an MR scanner without compromising spatial alignment with an anatomical sample during signal acquisition by the MR scanner.

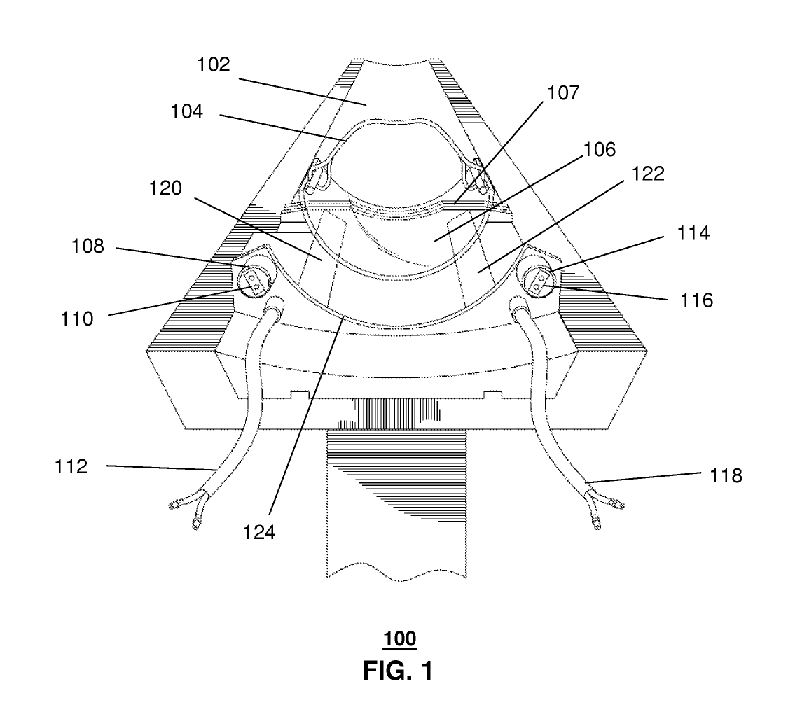

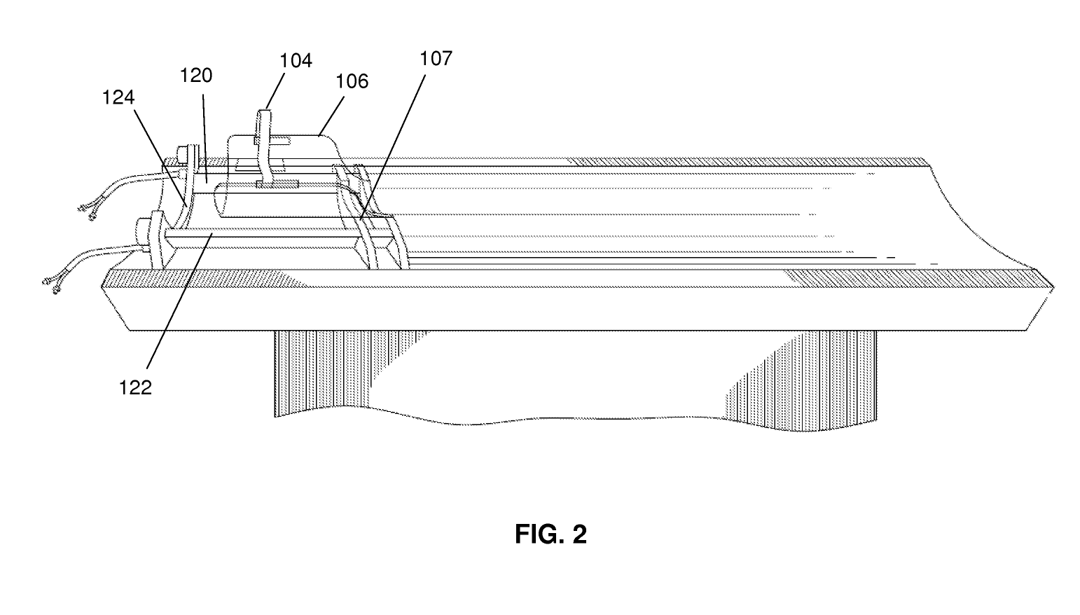

FIG. 1 depicts an illustrative embodiment of an apparatus 100 for performing magnetic resonance imaging (MRI) measurements on a sample such as a human being, animal species, or other biological sample. The apparatus 100 comprises a table 102 for positioning a patient in a rested position and a device 106 with a strap 104 and cushions for placement of, for example, a patient's head in a fixed position. The device 106 is attached to a supporting system 107 (see also FIG. 2) to create spacing between the patient's head and angled planks 120 and 122. The supporting system 107 further includes a guide 124 which together with the angled planks 120 and 122 facilitates the engagement of a cylindrical antenna as will be described shortly.

The guide 124 has two independent electromechanical connectors 108 and 114. The electromechanical connectors 108 and 114 have a male housing assembly with female electrical contacts 110 and 116 for engaging with electromechanical connectors of a cylindrical antenna. Each electrical contact of the electromechanical connectors in turn is connected to shielded coaxial cable pairs 112 and 118. Each coaxial cable pair provides shielded A and B radio frequency (RF) signals. FIG. 2 provides a side view of the apparatus 100.

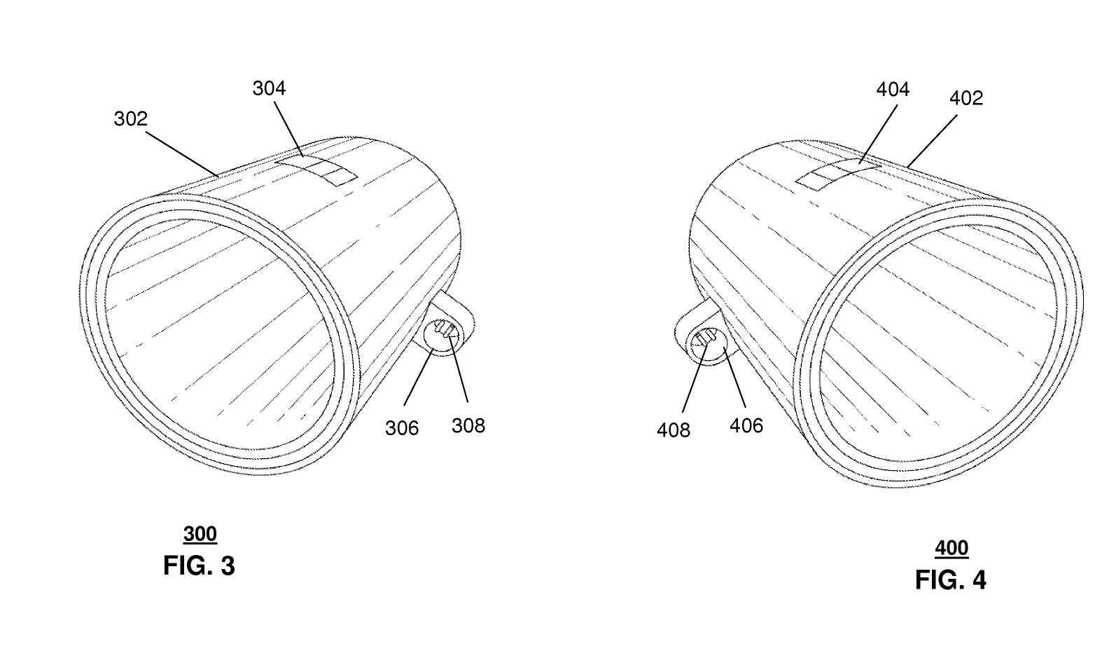

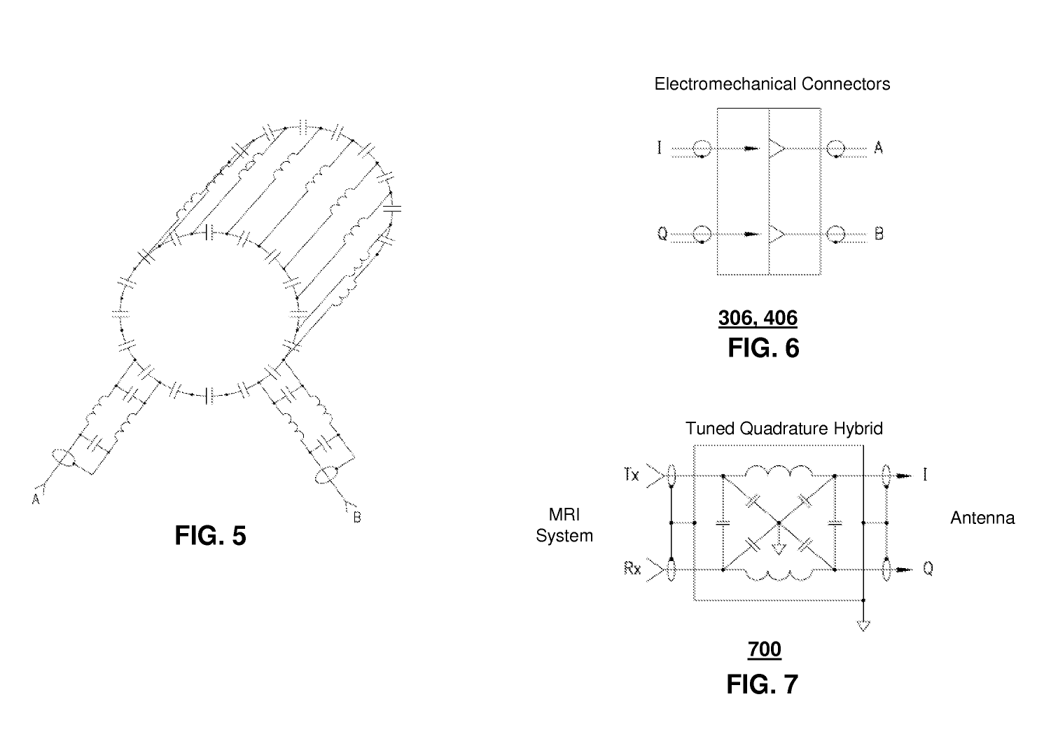

FIGS. 3-4 depict illustrative embodiments of first and second antennas 302 and 402 for engaging with the supporting system 107 of apparatus 100 of FIG. 1. The first antenna 302 comprises a window 304 which allows for some unobstructed viewing inside the cylindrical antenna. Attached to the right side of the first antenna 302 is an electromechanical connector 306 having a female housing assembly with male contacts 308. The electrical contacts 308 connect to a portion of circuitry embedded in each antenna 302 and 402 shown in FIG. 5 that form RF signals A and B. The second antenna 402 also has a window 404 for partial viewing into the cylinder, and an electromechanical connector 406 on the left side of the antenna 402 with a female housing assembly and male electrical contacts 408.

Each of the antennas 302 and 402 can utilize a common “bird-cage” antenna design as shown in FIG. 5 comprising a network of capacitors and inductors. Each of the antennas utilizes different circuit parameters so as to resonate at a frequency of an MR signal to be detected. The electromechanical connectors 306 and 406 have a pass-through connection from the A and B signals to corresponding quadrature signals I and Q as shown in FIG. 6. The quadrature signals are carried over coax cable pairs 112 and 118 to a device with a tuned quadrature hybrid circuit as shown in FIG. 7 which conveys RF transmit and receive (TX and RX) signals to an MRI system for processing. As noted earlier, each antenna 302 and 402 has electromechanical connectors 306 and 406 on opposite sides. Consequently, each antenna can be independently recognized by the MRI system according to the engagement position of the left or right electromechanical connector.

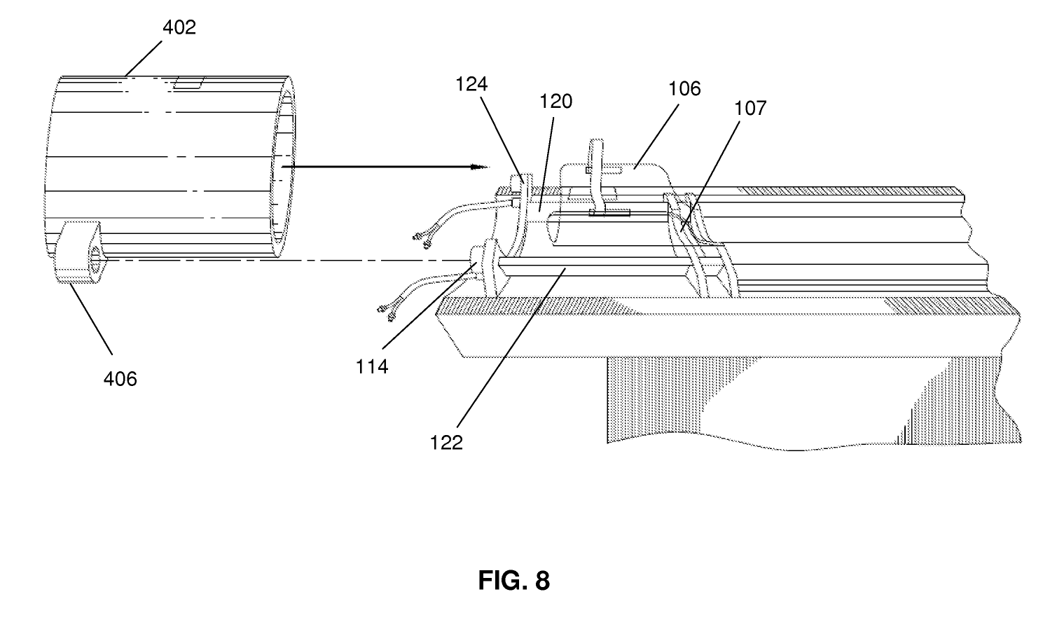

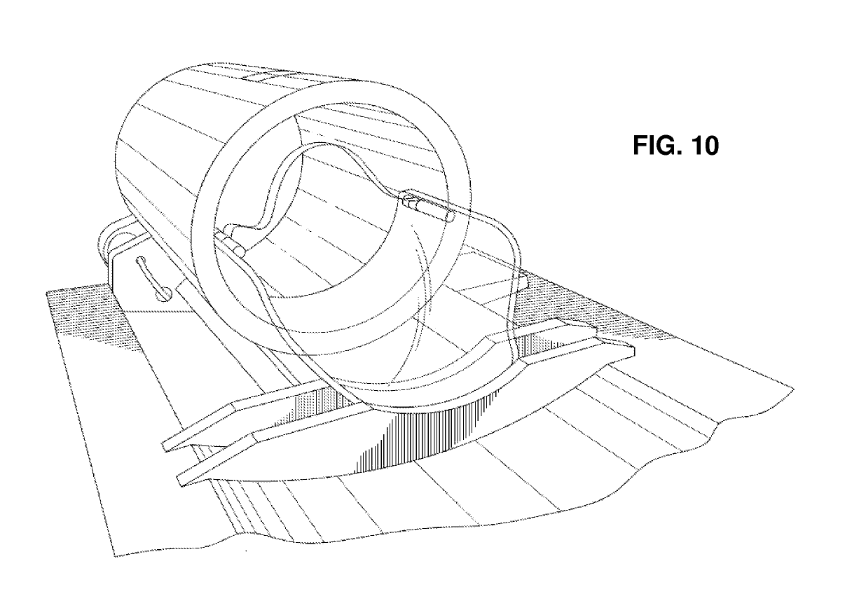

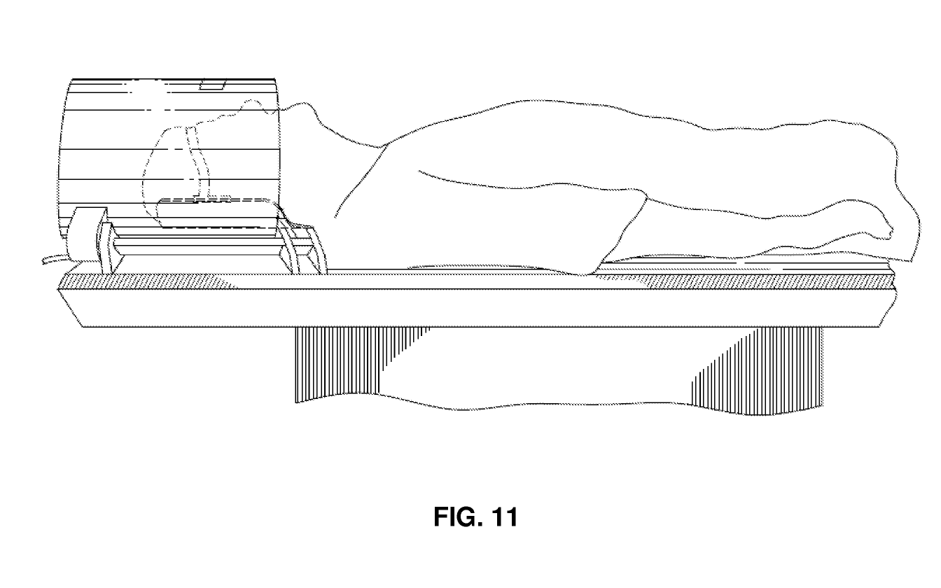

FIG. 8 depicts the engagement of the second antenna 402 with the supporting system 107. In this illustration the electromechanical connector 406 slideably engages with the electromechanical connector 114 of the support system 107. The guide 124 and the angled planks 120 and 122 serve to slideably guide the antenna 402 in position for engagement of connectors 406 and 114. FIG. 8 illustrates the antenna 402 fully engaged with the support system 107 and with device 106 (for illustration purposes referred to herein as head rest 106) which is positioned within the antenna cylinder. FIG. 10 provides a perspective view of the antenna 402 as it is being slideably coupled with the connectors 406 and 114. FIG. 11 illustrates a patient lying on the table 102 with his/her head on the head rest 106 fixed in place by the strap 104 and cushions.

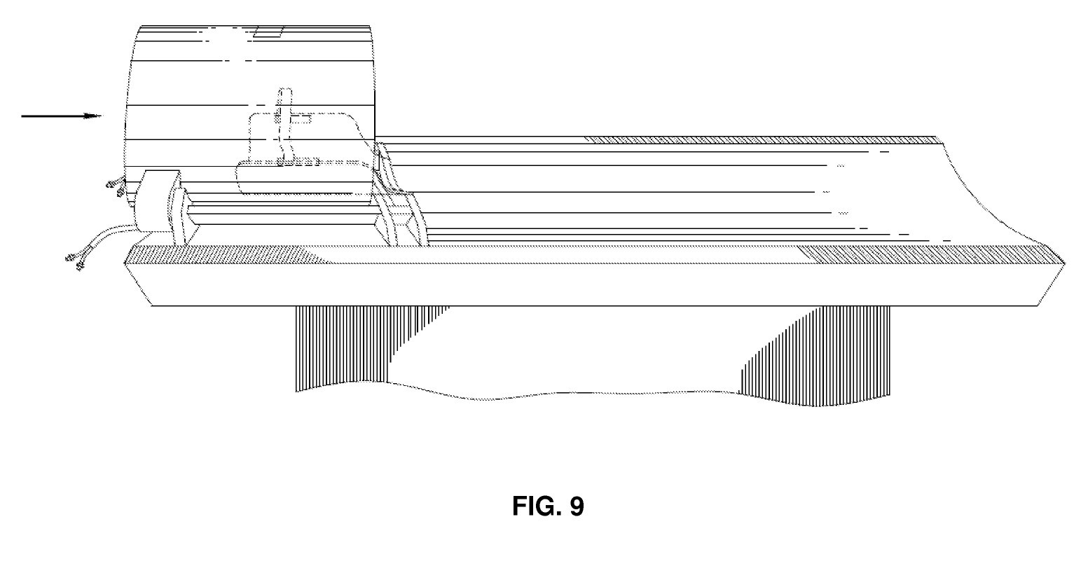

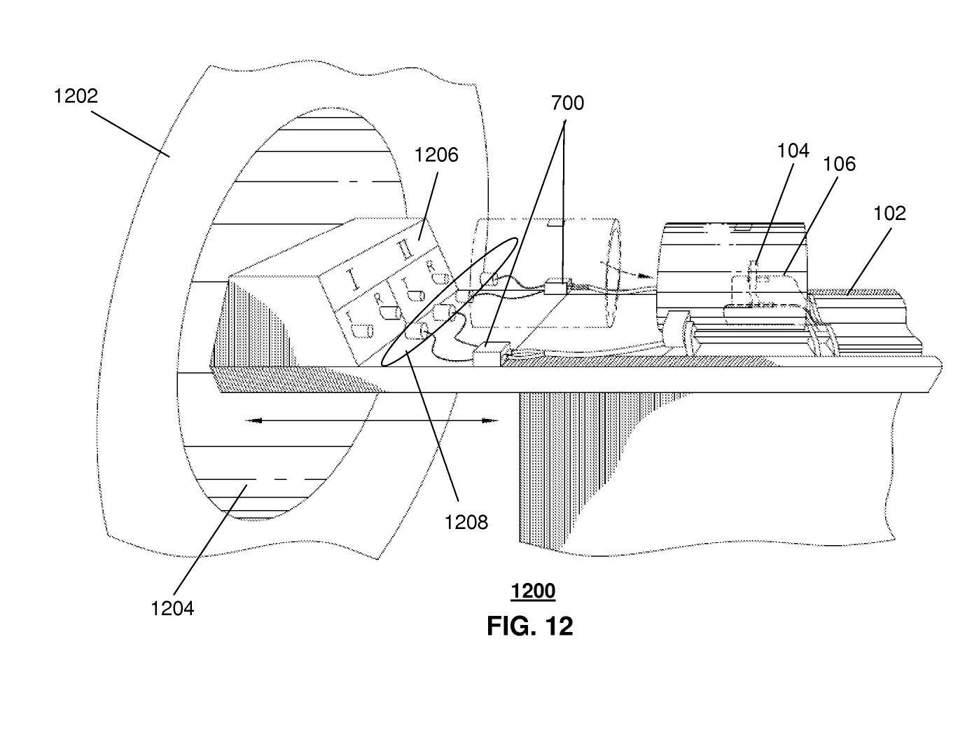

FIG. 12 depicts an MRI system 1202 with a common cavity 1204 in which the magnetic field is concentrated. The table 102 slides in and out of the cavity 1204 in a controlled fashion with common mechanical means used in MRI applications. The table 102 in this illustration has an interface 1202 that couples to a computing system (not shown) of the MRI 1202 for processing the RF TX and RX signals supplied by the antenna by way of the tuned quadrature hybrid circuits 700 shown in a fixed housing assembly on the table 102. The antennas 302 and 402 can be engaged and removed by the slideable technique illustrated in FIGS. 8-9. When a measurement is performed on a patient with one of the two antennas 302 or 402, the table 102 is pulled out of the cavity 1204 in a controlled fashion, and the antenna originally in place is slideably removed and replaced with the other antenna while the patient remains in a fixed position with the strap 104 and cushions. Once the replacement has taken place, the table 102 can be inserted back into the cavity 1204 in a position similar to the position used when taking measurements with the prior antenna. This process of antenna replacement without changing the alignment of the sample enables the MRI system to perform image registration directly without requiring a post-processing step.

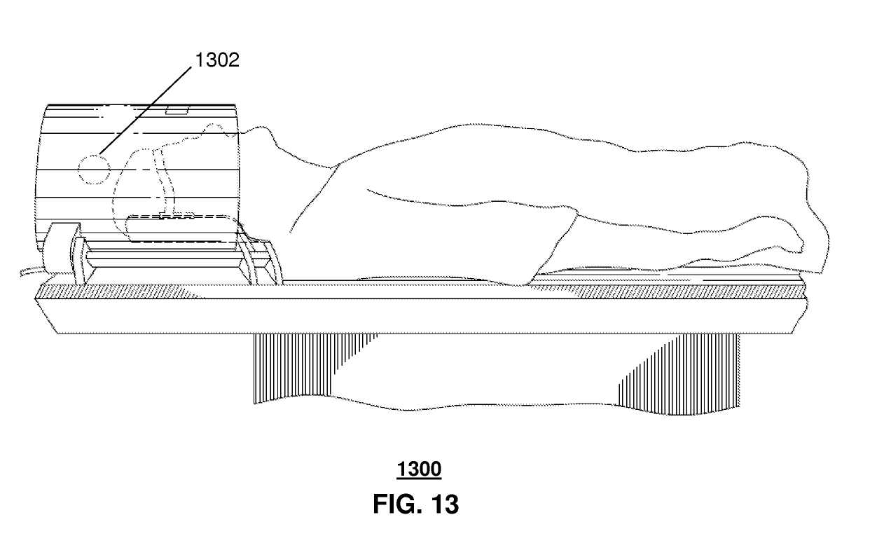

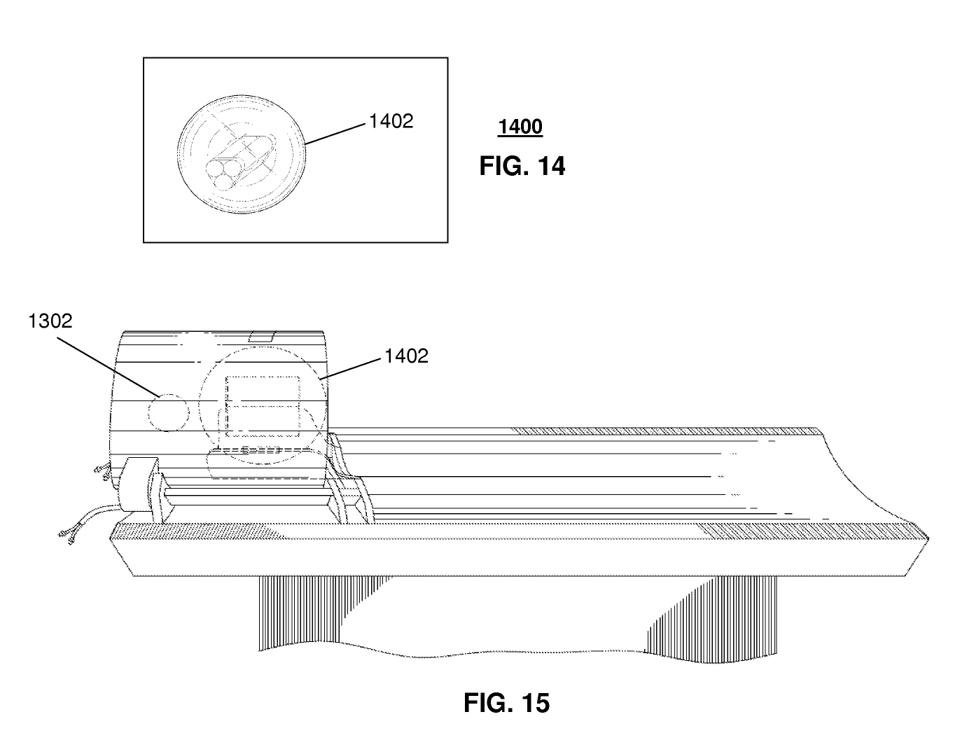

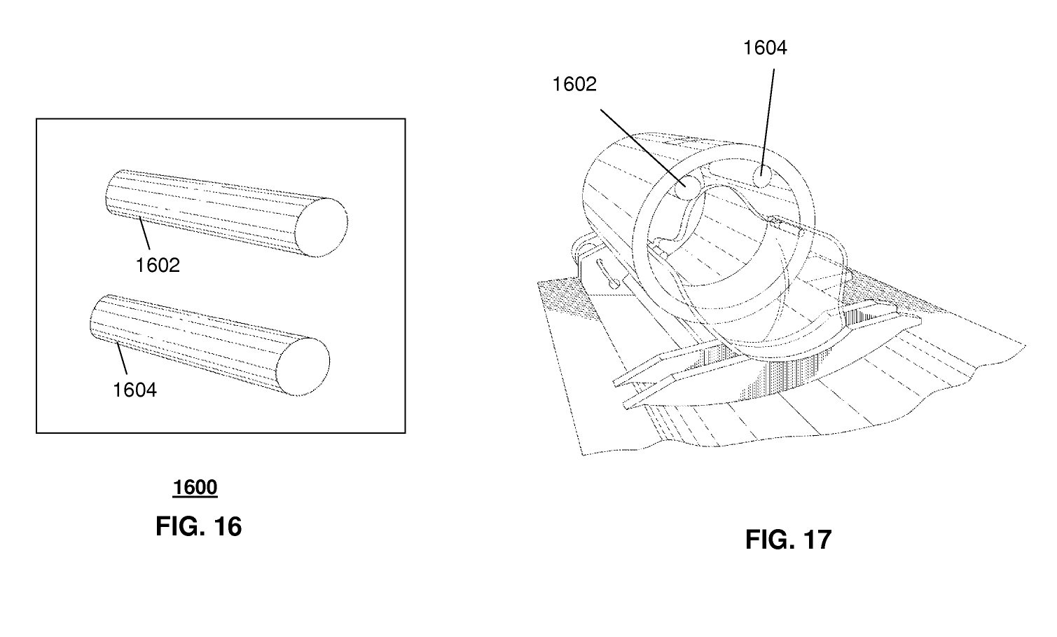

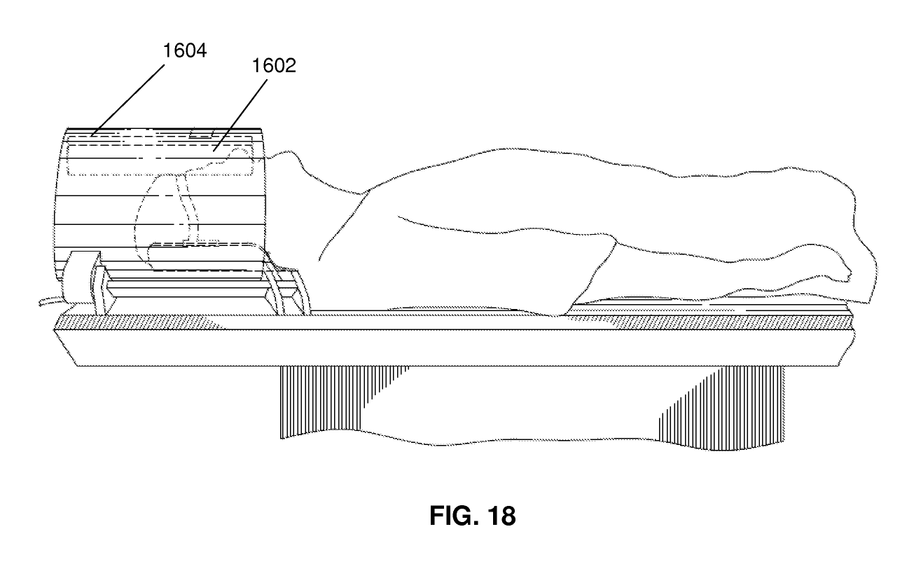

FIGS. 13-18 illustrate the use of calibration phantoms utilized for calibrating the MR signal from the antennas 302 and 402 in accordance with the present disclosure. Each of the phantom devices shown in these figures can include various concentrations of imaging isotopes which can be utilized in the calibration process. FIG. 13 depicts an illustrative embodiment of a normalization phantom 1302 in the shape of a small sphere utilized during MR signal measurements of a patient. FIG. 14 depicts a spherical phantom 1402 at the size of a common adult. FIG. 15 depicts an illustrative embodiment for using the normalization phantom 1302 and the spherical phantom 1402 for post MR signal processing calibration. FIG. 16 depicts an illustrative embodiment of two cylindrical phantoms 1602 and 1604. Two of the cylindrical shaped phantoms 1602 and 1604 can be placed in an inner surface of one of the antennas 302, 402 as shown in FIG. 17 for simultaneous calibration of measurements from a patient as shown in FIG. 18.

### Application of Multiple Images Acquired with Co-Registration Quantification for Metabolic MR Imaging

One purpose of the measurement of MR images at multiple frequencies is to produce accurate quantitative maps of metabolite concentrations and metabolic rates in imaging times that are acceptable to patients. This requires the highest signal intensity at the lowest noise level (highest signal-to-noise ratio, SNR) in the least time. The use of different antennae tuned to single frequencies ensures the most efficient antenna performance (highest SNR). The acquisition of spatially co-registered images at different frequencies by maintaining head position during changes of antennae as shown in FIG. 11 allows information from one frequency that is most efficient for obtaining specific information to be combined with images from a different frequency that contains biological information.

Unlike current proton clinical imaging that uses an arbitrary intensity scale, such metabolic MR imaging produces a quantitative bioscale. A quantitative bioscale in the present context can mean spatial distributions of metabolite concentrations that have direct biochemical interpretations of normal and diseased biological states. The interpretation of the metabolic map as a bioscale can be readily displayed using a color scale in which different thresholds of color represent biologically significant phases of a metabolic process. The metabolic process could be as severe as loss of tissue viability, or as benign as stages in normal tissue function.

Quantification requires correction of the imperfections of the imaging method caused by inhomogeneities in the main static magnetic field (B0) and the non-uniformity of the antennae sensitivity (B1) across the field of view. An embodiment for correcting B0 and B1 is described below.

Although images from different sources (e.g. Positron Emission Tomography-PET and Computed Tomography-CT) have been combined in other settings, image registration has been performed as a post-processing step to overlay one image over another. This approach works for qualitative images if the image distortions in the two images are not large. Image processing errors have lead to the new combined technology of CT and PET in the same device to acquire co-registered data. The present disclosure achieves this same goal of acquired co-registered data for different MR antennae.

### B0 Inhomogeneity Correction

The insertion of a sample such as human into a static magnetic field of an MR scanner distorts the homogeneity of the magnetic field. These inhomogeneities result in small, localized perturbations of the resonant frequency of the signal being detected. While current magnets are very homogeneous, the insertion of the human into the magnetic field results in considerable distortion of that field. Changes in position and orientation of the human alter these field distortions. If these sample-induced field imperfections are ignored by assuming a homogenous static magnet field, the concomitant frequency errors distort the images by altering the signal intensity and inaccurately placing that signal within the image. This error can be manifested in a number of ways including blurring, geometric distortions and, most importantly for quantification, signal loss. If left uncorrected, these artifacts produce an inaccurate metabolic map, both anatomically and quantitatively.

Static field inhomogeneities can be corrected by measuring the magnetic field after the human has been placed in the magnetic field. This can be done by shimming the main magnetic field by applying small correction magnetic gradients (room temperature shims) and by measuring the resultant B0 field. This B0 field correction map can be incorporated into the image reconstruction process of other images to remove the effect of the inhomogeneities of the static magnetic field caused by the sample.

For example, the shimming correction and mapping of B0 is most efficiently performed using the proton frequency that has the highest MR sensitivity in humans. Other signals such as from sodium can be used but are more time consuming. The resultant corrections can then be applied to a second frequency, but only if the position of the human does not change in the magnetic field. Any change in location or orientation of the human alters the B0 distortions and invalidates the correction. For this reason, a sample is maintained in a fixed position while a change of antenna takes place.

The B0 mapping over the human must also be performed for the calibration phantom in the same way as done for the human. The homogeneity of the actual static magnetic field with the human or phantom present is computed from the phase difference between two or more complex MR images collected with different echo-times. The images used to compute the static field measurement can be from the same nucleus as the metabolic data to be corrected (e.g., sodium data used to compute a B0 field map to correct sodium images) or from a different nucleus as the data to be corrected (e.g., proton data used to compute a field map to correct sodium data). If the static magnetic field correction is applied to a different nucleus from that used to determine it, a correction factor of the ratio of the two gyromagnetic ratios is applied. The essential requirement is that the sample location and orientation within the B0 magnetic field does not change between the measurements from the different antennae.

### Correction of B1 Non-Uniformity

The arbitrarily scaled MR image voxel intensities are converted into biologically meaningful metabolic concentrations. This can be done in two ways. Either external phantoms of known concentration can be placed in the same field of view as the human or separate acquisitions can be performed using the same antenna with equal electrical loading for the human and calibration phantom. Both methods require that the images acquired from the human and the calibration phantoms have the B1 sensitivity correction determined with the same antenna. The B0 correction can be determined from any antenna and is applied prior to the B1 correction.

### Quantification with Separate Image Acquisitions For the Human and Calibration Phantom

An external calibration phantom can consist of two or more (e.g. three) vials as shown in FIG. 14 with different metabolite concentrations spread over the biological range. The phantom is imaged under the same conditions as the human subject to derive the calibration curve. This calibration phantom is made to closely match the electrical loading of the human to ensure similar antenna sensitivity during data acquisitions from both human and phantom. Small changes in antenna sensitivity due to small differences in antenna loading for human and phantom can still exist. These differences can be corrected using a small sphere 1302 filled with a sample containing the signal of interest placed at the same location in the antenna during both phantom and human imaging. This signal difference between the human and phantom due to different antenna loading is used to normalize the signal intensity between the human and phantom images to allow accurate quantification of signal intensity in the human from the signal intensities in the phantom.

### Quantification with Single Acquisition for the Human and Calibration Phantoms

Another method of quantification that avoids the use of separate acquisitions for the calibration phantom and human is to use separate calibration phantoms in the same field of view as the human imaging. These phantoms must be placed around the human in the limited space available as shown in FIGS. 16-18. Usually only two phantoms are required spanning the biological concentration range. Although these phantoms can produce image distortions, these can be corrected by B0 mapping as described above. The phantoms are also close to the antenna and so experience a different B1 field from the human. This sensitivity difference can be corrected by B1 mapping as described below. This method avoids the normalization step and acquires only a single acquisition for the human and calibration phantoms. For the purposes of this device, the B0 mapping can be performed with a different antenna from that used to acquire the metabolic signal. The B1 map can be made with the same antenna as the metabolic map. In this case, only one B1 map is required as the phantoms and human images are acquired simultaneously.

### B1 Sensitivity Mapping

As the antenna sensitivity is usually inhomogeneous across biological samples, there are spatially varying quantification errors. Antenna sensitivity includes both the transmit sensitivity (B1+) and the receive sensitivity (B1−). According to the principle of reciprocity, one can reasonably assume transmit and receive sensitivities are the same at low frequencies. As metabolic images are acquired under fully relaxed conditions, the three-dimensional transit sensitivity can be estimated using the double flip angle approach by varying the transmit gain:

S₁=sᵣρ sin(2θ),S₂=Sᵣρ sin(θ),θ=cos⁻¹(S₁S₂/2)

where S₁ and S₂ are the corresponding image voxel intensities with 1x and 2x transmit power, and consequently excitation angles of θ and 2θ, and where sᵣ is the image receive sensitivity and is proportional to θ based on the reciprocity assumption. ρ is a measure of image spin density that is of interest. cos⁻¹(y) is the inverse cosine of y. The transmit power can be adjusted so that the maximum flip angles across the field of view are less than 180 degrees. The antenna sensitivity corrected images are then: \hat{ρ}=S₁/(θsin2θ)·\hat{ρ} differs from ρ by a constant factor due to the scale of receive sensitivity.

The images can be collected with a nominal flip angle pair of (90°, 45°) or one can use a flip angle pair of (108°, 54°) to maximize the combined SNR when images from both flip angles are averaged after antenna sensitivity correction. The individual images can be low pass filtered to improve B1 mapping. For the use of a separate calibration phantom method, both the phantom and human images can be corrected for antenna sensitivity and then normalized by the corresponding signal intensity of the normalization sphere in both set of images. A linear calibration curve (in the form of S=ax+b, where S is the unknown metabolic concentration to be determined, a and b are constants, and x is the normalized and antenna-sensitivity corrected voxel signal intensity) is then derived from the normalized signal intensities in the calibration phantom. Non-linear functions can also be used that can be more appropriate to the SNR of the data.

In practice, obtaining the B1 map accurately from the normalization sphere can be limited by low SNR. An alternative method to the normalization sphere is to use a common central region of interest within the human and phantom images for normalization. Assuming that the antenna sensitivity varies very slowly over a region of interest at the isocenter of the field of view (or other locations), the average B1 sensitivity can be calculated for that region in the calibration phantom and human images.

For the phantom, this region of interest can contain the two or more (e.g. three) calibration vials, the signal intensities of which are then antenna sensitivity corrected, and used to generate the calibration curve. The average B1 sensitivity from the same Region of Interest (ROI) in the human images is also calculated and used for normalization with the phantom images. The B1 map over the whole brain is generated to correct for the antenna sensitivity over the entire human image and then normalized by the B1 sensitivity in the region of interest so that the calibration curve can be applied to obtain the metabolite concentration map. The single acquisition method requires no normalization as the images of the human and calibration phantoms are acquired simultaneously with identical electrical loading of the antenna.

From the foregoing descriptions, it would be evident to an artisan with ordinary skill in the art that the aforementioned embodiments can be modified, reduced, or enhanced without departing from the scope and spirit of the claims described below. For example, the present illustration shows two antennas 302 and 402. The apparatus 100 can be designed for three or more antennas. Additionally, the apparatus 100 can be modified so that antenna engagement mechanism is performed by other common mechanical means other than a slideable assembly as presented by the disclosure.

Other suitable modifications can be applied to the present disclosure. Accordingly, the reader is directed to the claims for a fuller understanding of the breadth and scope of the present disclosure.

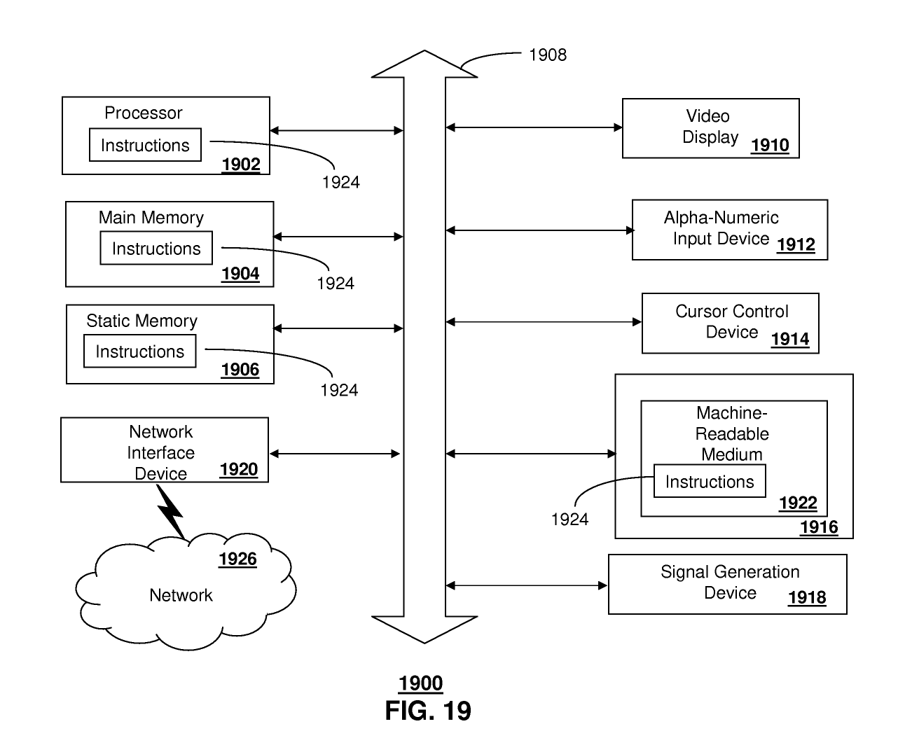

FIG. 19 depicts an exemplary diagrammatic representation of a machine in the form of a computer system 1900 within which a set of instructions, when executed, may cause the machine to perform any one or more of the methodologies discussed above. The computer system 1900 can be an integral part of the MRI system 1202 discussed above or coupled thereto. The computer system 1900 can be adapted to process signals captured by the antennas 302 and 402. In some embodiments, the machine operates as a standalone device. In some embodiments, the machine may be connected (e.g., using a network) to other machines. In a networked deployment, the machine may operate in the capacity of a server or a client user machine in server-client user network environment, or as a peer machine in a peer-to-peer (or distributed) network environment.

The machine may comprise a server computer, a client user computer, a personal computer (PC), a tablet PC, a laptop computer, a desktop computer, a control system, a network router, switch or bridge, or any machine capable of executing a set of instructions (sequential or otherwise) that specify actions to be taken by that machine. It will be understood that a device of the present disclosure includes broadly any electronic device that provides voice, video or data communication. Further, while a single machine is illustrated, the term “machine” shall also be taken to include any collection of machines that individually or jointly execute a set (or multiple sets) of instructions to perform any one or more of the methodologies discussed herein.

The computer system 1900 may include a processor 1902 (e.g., a central processing unit (CPU), a graphics processing unit (GPU), or both), a main memory 1904 and a static memory 1906, which communicate with each other via a bus 1908. The computer system 1900 may further include a video display unit 1910 (e.g., a liquid crystal display (LCD), a flat panel, a solid state display, or a cathode ray tube (CRT)). The computer system 1900 may include an input device 1912 (e.g., a keyboard), a cursor control device 1914 (e.g., a mouse), a disk drive unit 1916, a signal generation device 1918 (e.g., a speaker or remote control) and a network interface device 1920.

The disk drive unit 1916 may include a machine-readable medium 1922 on which is stored one or more sets of instructions (e.g., software 1924) embodying any one or more of the methodologies or functions described herein, including those methods illustrated above. The instructions 1924 may also reside, completely or at least partially, within the main memory 1904, the static memory 1906, and/or within the processor 1902 during execution thereof by the computer system 1900. The main memory 1904 and the processor 1902 also may constitute machine-readable media.

Dedicated hardware implementations including, but not limited to, application specific integrated circuits, programmable logic arrays and other hardware devices can likewise be constructed to implement the methods described herein. Applications that may include the apparatus and systems of various embodiments broadly include a variety of electronic and computer systems. Some embodiments implement functions in two or more specific interconnected hardware modules or devices with related control and data signals communicated between and through the modules, or as portions of an application-specific integrated circuit. Thus, the example system is applicable to software, firmware, and hardware implementations.

In accordance with various embodiments of the present disclosure, the methods described herein are intended for operation as software programs running on a computer processor. Furthermore, software implementations can include, but not limited to, distributed processing or component/object distributed processing, parallel processing, or virtual machine processing can also be constructed to implement the methods described herein.

The present disclosure contemplates a machine readable medium containing instructions 1924, or that which receives and executes instructions 1924 from a propagated signal so that a device connected to a network environment 1926 can send or receive voice, video or data, and to communicate over the network 1926 using the instructions 1924. The instructions 1924 may further be transmitted or received over a network 1926 via the network interface device 1920.

While the machine-readable medium 1922 is shown in an example embodiment to be a single medium, the term “machine-readable medium” should be taken to include a single medium or multiple media (e.g., a centralized or distributed database, and/or associated caches and servers) that store the one or more sets of instructions. The term “machine-readable medium” shall also be taken to include any medium that is capable of storing, encoding or carrying a set of instructions for execution by the machine and that cause the machine to perform any one or more of the methodologies of the present disclosure.

The term “machine-readable medium” shall accordingly be taken to include, but not be limited to: solid-state memories such as a memory card or other package that houses one or more read-only (non-volatile) memories, random access memories, or other re-writable (volatile) memories; magneto-optical or optical medium such as a disk or tape; and/or a digital file attachment to e-mail or other self-contained information archive or set of archives is considered a distribution medium equivalent to a tangible storage medium. Accordingly, the disclosure is considered to include any one or more of a machine-readable medium or a distribution medium, as listed herein and including art-recognized equivalents and successor media, in which the software implementations herein are stored.

Although the present specification describes components and functions implemented in the embodiments with reference to particular standards and protocols, the disclosure is not limited to such standards and protocols. Each of the standards for Internet and other packet switched network transmission (e.g., TCP/IP, UDP/IP, HTML, HTTP) represent examples of the state of the art. Such standards are periodically superseded by faster or more efficient equivalents having essentially the same functions. Accordingly, replacement standards and protocols having the same functions are considered equivalents.

The illustrations of embodiments described herein are intended to provide a general understanding of the structure of various embodiments, and they are not intended to serve as a complete description of all the elements and features of apparatus and systems that might make use of the structures described herein. Many other embodiments will be apparent to those of skill in the art upon reviewing the above description. Other embodiments may be utilized and derived therefrom, such that structural and logical substitutions and changes may be made without departing from the scope of this disclosure. Figures are also merely representational and may not be drawn to scale. Certain proportions thereof may be exaggerated, while others may be minimized. Accordingly, the specification and drawings are to be regarded in an illustrative rather than a restrictive sense.

Such embodiments of the inventive subject matter may be referred to herein, individually and/or collectively, by the term “invention” merely for convenience and without intending to voluntarily limit the scope of this application to any single invention or inventive concept if more than one is in fact disclosed. Thus, although specific embodiments have been illustrated and described herein, it should be appreciated that any arrangement calculated to achieve the same purpose may be substituted for the specific embodiments shown. This disclosure is intended to cover any and all adaptations or variations of various embodiments. Combinations of the above embodiments, and other embodiments not specifically described herein, will be apparent to those of skill in the art upon reviewing the above description.

The Abstract of the Disclosure is provided to comply with 37 C.F.R. §1.72(b), requiring an abstract that will allow the reader to quickly ascertain the nature of the technical disclosure. It is submitted with the understanding that it will not be used to interpret or limit the scope or meaning of the claims. In addition, in the foregoing Detailed Description, it can be seen that various features are grouped together in a single embodiment for the purpose of streamlining the disclosure. This method of disclosure is not to be interpreted as reflecting an intention that the claimed embodiments require more features than are expressly recited in each claim. Rather, as the following claims reflect, inventive subject matter lies in less than all features of a single disclosed embodiment. Thus the following claims are hereby incorporated into the Detailed Description, with each claim standing on its own as a separately claimed subject matter.

What is claimed is:

1. A device, comprising:
a plurality of antennas to couple to a Magnetic Resonance Imaging (MRI) system;
wherein the MRI system measures a first set of signals from a first one of the antennas while the first antenna is positioned over an anatomical sample and engaged with the MRI system;
wherein the MRI system measures a second set of signals from a second one of the antennas engaged with the MRI system after the second antenna replaces the first antenna while maintaining image alignment with the anatomical sample.

2. The device of claim 1, wherein at least a portion of the plurality of antennas are single-tuned antennas, each of the single-tuned antennas tuned to a different resonant frequency.

3. The device of claim 1, wherein the anatomical sample is physically supported by the MRI system independent of the placement of the first and second antennas.

4. The device of claim 1, wherein the plurality of antennas each have a geometry adapted to the anatomical sample.

5. The device of claim 4, wherein the geometry of each of the plurality of antennas is substantially similar.

6. The device of claim 1, wherein each of the plurality of antennas slidably engages with the MRI system.

7. The device of claim 1, wherein the MRI system comprises a sled to slidably engage with each of the plurality of antennas.

8. The device of claim 7, wherein the sled rests on a table of the MRI system that supports the anatomical sample.

9. The device of claim 1, wherein the first and second signals correspond to radio frequency signals representative of at least one of proton signals and non-proton signals.

10. The device of claim 9, wherein the non-proton signals correspond to at least one of sodium signals, oxygen signals, carbon signals, nitrogen signals, and phosphorus signals, and wherein each of the plurality of antennas when engaged with the MRI system cover at least a portion of the anatomical sample.

11. The device of claim 1, wherein each of the plurality of antennas electromechanically makes contact with the MRI system when engaged.

12. The device of claim 11, wherein each of the plurality of antennas has a uniquely positioned electromechanical contact, and wherein the MRI system detects which of the plurality of antennas is engaged with the MRI system according to the positions of the electromechanical contacts.

13. The device of claim 12, wherein the MRI system determines which resonant frequency the detected antenna is tuned to according to its uniquely positioned electromechanical contact.

14. The device of claim 1, wherein the MRI system utilizes at least one of the first and second signals to produce at least one of metabolic images, physiological images, anatomic images, and functional images.

15. The device of claim 1, wherein the MRI system utilizes at least one of the first and second signals to produce a quantitative bioscale map of a metabolite concentration or metabolic rate.

16. The device of claim 1, wherein the first and second signals are co-registered in space.

17. The device of claim 1, wherein each of the plurality of antennas detachably engages with the MRI system.

18. A Magnetic Resonance Imaging (MRI) system comprising a Magnetic Resonance (MR) scanner to selectively couple to one of a plurality of antennas without compromising spatial alignment with an anatomical sample during signal acquisition by the MR scanner.

19. The MRI system of claim 18, comprising a computing device to process signals collected from at least two of the antennas.

20. The MRI system of claim 18, wherein the plurality of antennas are slidably coupled to a sled located on a sampling table of the MR scanner.

21. The MRI system of claim 18, comprising a computing device adapted to control selective coupling between the MR scanner and the plurality of antennas without compromising spatial co-registration with the anatomical sample.

22. The MRI system of claim 18, wherein the anatomical sample corresponds to a human patient.

23. A computer-readable storage medium, comprising computer instructions for processing signals received from at least two of a plurality of antennas that selectively couple to a Magnetic Resonance (MR) scanner without compromising spatial alignment with an anatomical sample during signal acquisition by the MR scanner.

24. The storage medium of claim 23, comprising computer instructions for generating from the processed signals at least one of metabolic images, physiological images, anatomic images, and functional images.

25. A method, comprising selectively coupling one of a plurality of antennas to a Magnetic Resonance (MR) scanner without compromising spatial alignment with an anatomical sample during signal acquisition by the MR scanner.

26. The method of claim 25, comprising generating from the processed signals at least one of metabolic images, physiological images, anatomic images, and functional images.

27. The method of claim 25, comprising:
receiving MR signals from the plurality of antennas; and
combining the MR signals to achieve quantification of the spatial distribution of a biochemical parameter.

28. The method of claim 27, comprising measuring from a first of the plurality of antennas a map of a main static magnetic field (B0) that has been perturbed by the anatomical sample during signal acquisition by the MR scanner.

29. The method of claim 28, comprising replacing the first of the plurality of antennas with a second one of the plurality of antennas without compromising spatial alignment with the anatomical sample.

30. The method of claim 29, comprising measuring from the second antenna a sensitivity of the second antenna (B1) and a metabolic image from an element in the periodic table that generates at least one of the MR signals.

31. The method of claim 30, comprising converting the metabolic image into a quantitative map.

32. The method of claim 31, comprising converting the metabolic image into the quantitative map by measuring signals from a normalization phantom and a calibration phantom that emulates in part the anatomical sample, wherein the normalization and calibration phantoms comprise one or more concentrations of imaging isotopes.

33. The method of claim 31, comprising converting the metabolic image into a quantitative map while the second antenna measures the sensitivity of the second antenna (B1) and the metabolic image, wherein the second antenna is coupled to at least two calibration phantoms.

34. The method of claim 33, wherein the at least two calibration phantoms are cylindrical phantoms, each with a different concentration of imaging isotopes.

35. The method of claim 31, wherein the quantitative map corresponds to a metabolite concentration.

36. The method of claim 35, comprising:
measuring the metabolite concentration over time; and
determining a metabolic rate from a change in the metabolite concentration over time.

37. The method of claim 31, comprising determining from the quantitative map a bioscale.

38. The method of claim 37, wherein the bioscale comprises a plurality of thresholds.

39. The method of claim 38, comprising presenting the quantitative map according the plurality of thresholds of the bioscale.

40. The method of claim 39, wherein the presentation includes an identification of a degree of health of the anatomical sample.

41. The method of claim 40, wherein the degree of health depicts at least one of a gradation of function of the anatomical sample, and progression of health of the anatomical sample.

42. The method of claim 39, wherein the presentation includes at least one of an identification of healthy, unhealthy, and incurable portions of the anatomical sample.

43. The method of claim 31, wherein the metabolic image comprises a metabolic image of the anatomical sample, and at least one metabolic image of a corresponding at least one calibration phantom, comprising:
correcting image distortions in the metabolic image according to the B0 map;
correcting the metabolic image for non-uniformity in the sensitivity of the second antenna according to the B1 map; and
converting signal intensities in the metabolic image into a metabolite concentration according to a metabolic image of the anatomical sample and the at least one metabolic image of the at least one calibration phantom.
